(19) United States
(12) Patent Application Publication
(10) Pub. No.: US 2023/0344197 A1
(43) Pub. Date: Oct. 26, 2023

(54) SEMICONDUCTOR LASER DEVICE WITH FIRST ORDER DIFFRACTION GRATING EXTENDING TO FACET

(71) Applicant: NLIGHT, INC., Camas, WA (US)

(72) Inventor: Manoj KANSKAR, Portland, OR (US)

(73) Assignee: NLIGHT, INC., Camas, WA (US)

(21) Appl. No.: 17/640,646

(22) PCT Filed: Nov. 11, 2021
(86) PCT No.: PCT/US2021/059007

§ 371 Date: Mar. 4, 2022

Related U.S. Application Data
(60) Provisional application No. 63/116,742, filed on Nov. 20, 2020.

(51) Int. Cl. H01S 5/12; H01S 5/028; H01S 5/32

(52) U.S. Cl. CPC H01S 5/1203; H01S 5/0287; H01S 5/3211

(57) ABSTRACT

Some embodiments may include a semiconductor laser device comprising: an active layer to generate light; a front facet positioned at a first end of said active layer, with an AR coating or PR coating; a rear facet positioned on a second opposite end of said active layer thereby forming a resonator between said front facet and said rear facet; and a first order diffraction grating positioned within said resonator along only a portion of the length of said active layer, wherein the semiconductor laser device is arranged to emit light from both ends, and the diffraction grating has two non-contiguous segments each extending to one of the facets; or a single end, wherein the rear facet is a rear light reflecting facet with an HR-coating. Other embodiments may be disclosed and/or claimed.

### PRIORITY

This application is a US national phase application, which claims priority to PCT Application No. PCT/US2021/059007, filed Nov. 11, 2021, which claims priority to U.S. Provisional Application No. 63/116,742 filed on Nov. 20, 2020, entitled SEMICONDUCTOR LASER DEVICE WITH FIRST ORDER DIFFRACTION GRATING EXTENDING TO FACET, which is incorporated by reference herein.

### TECHNICAL FIELD

The present disclosure relates to laser diodes.

### BACKGROUND

Fiber lasers are widely used in industrial processes (e.g., cutting, welding, cladding, heat treatment, etc.) In some fiber lasers, the optical gain medium includes one or more active optical fibers with cores doped with rare-earth element(s). The rare-earth element(s) may be optically excited (“pumped”) with light from one or more semiconductor laser sources. There is great demand for high power and high efficiency diode lasers, the former for power scaling and price reduction (measured in $/Watt) and the latter for reduced energy consumption and extended lifetime.

### BRIEF DRAWINGS DESCRIPTION

The accompanying drawings, wherein like reference numerals represent like elements, are incorporated in and constitute a part of this specification and, together with the description, explain the advantages and principles of the presently disclosed technology.

FIG. 1A illustrates a longitudinal cross-sectional view of a semiconductor laser device with a buried grating located at a light reflecting facet, according to various embodiments.

FIG. 1B illustrates a top view of a section of the semiconductor laser device of FIG. 1A, taken from the perspective of arrows A of FIG. 1A.

FIG. 1C is a graph showing reflectivity spectrum of the AR-coating of the front facet illustrated in FIGS. 1A-B.

FIG. 1D is a graph showing effective reflectivity spectrum due to a combination of the HR-coating of the rear facet illustrated in FIGS. 1A-B in combination with the buried grating illustrated in FIGS. 1A-B.

FIG. 2A illustrates a longitudinal cross-sectional view of another semiconductor laser device with a buried grating located at a light emitting facet, according to various embodiments.

FIG. 2B is a graph showing reflectivity spectrum of the AR-coating of the front facet illustrated in FIG. 2A.

FIG. 2C is a graph showing the dependence of peak reflectivity with grating length at the AR-coated front facet.

FIG. 3 illustrates a longitudinal cross-sectional view of another semiconductor laser device with a diffraction grating formed from a deposited oxide film over-layer atop a surface semiconductor grating.

FIG. 4 illustrates a longitudinal cross-sectional view of another semiconductor laser device with a diffraction grating formed from a deposited metal layer over-layer atop a surface semiconductor grating.

FIG. 5A illustrates a longitudinal cross-sectional view of another semiconductor laser device to emit light from both ends, in which the diffraction gratings are buried.

FIG. 5B illustrates a longitudinal cross-sectional view of another semiconducter laser device to emit light from both ends, with a buried diffraction grating.

FIG. 6A illustrates a longitudinal cross-sectional view of another semiconductor laser device to emit light from both ends, in which the diffraction gratings are not buried.

FIG. 6B illustrates a longitudinal cross-sectional view of another semiconductor laser device to emit light from both ends, with a diffraction grating that is not buried.

FIG. 7 illustrates a longitudinal cross-sectional view of another semiconductor laser device with a surface semiconductor grating located at the front facet, in which one of the cladding layers is thinner than the other cladding layer.

### DETAILED DESCRIPTION

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items. The systems, apparatus, and methods described herein should not be construed as limiting in any way. Instead, the present disclosure is directed toward all novel and non-obvious features and aspects of the various disclosed embodiments, alone and in various combinations and sub-combinations with one another. The term “or” refers to “and/or,” not “exclusive or” (unless specifically indicated).

The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation. Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus.

Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art. In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

Yb-doped fiber lasers and amplifiers are becoming strong contenders as sources used in power-scalable spectrally beam combined and coherently beam combined high energy laser systems. Power levels well beyond 100 kW is anticipated for these applications, with pumping at ˜975 nm. The primary benefits for pumping a fiber laser/amplifier on this strong absorption peak are a reduction in cost due to the need for shorter fiber and higher threshold power for nonlinear effects such as Stimulated Raman Scattering (SRS) and Stimulated Brillouin Scattering (SBS). But the absorption band of Yb-doped fiber is very narrow (<5 nm at the FWHM) and very sharp drop-off occurs around the peak near ˜975 nm. An obvious drawback to pumping this narrow absorption band is that the emitting wavelength of the laser diodes must be tightly controlled to the specified wavelength. A small change in the emitting wavelength of the diodes results in a substantial reduction in the absorption cross-section and enormous amount of unabsorbed pump power will have to be managed making it very impractical in DEW systems. Since the emitting wavelength is directly related to the operating temperature, the coolant temperature must be tightly controlled in order to maintain the proper wavelength as the pump power is increased. This adds complexity to the system increasing cost and SWAP while also requiring setup and stabilization time for the coolant system which is not realistic in operational scenarios. High-power GaAs-based diode lasers produce optical power with extremely high efficiencies, but the spectrum of these Fabry Perot laser diodes is too broad for many applications (>4-5 nm with 95% power content). Narrow spectra (<0.5 nm) can be achieved using monolithically integrated gratings. However, it remains challenging to develop designs that simultaneously achieve high power, high efficiencies and narrow spectra over a wide operating temperature and electrical current (optical power) ranges.

Yb-doped fiber lasers and amplifiers are becoming strong contenders as sources used in power-scalable spectrally beam combined and coherently beam combined high energy laser systems. Power levels well beyond 100 kW is anticipated for these applications. Pumping these fiber amplifiers at ˜975 nm has become an imperative. The primary benefits for pumping a fiber laser/amplifier on this strong absorption peak are a reduction in cost due to the need for shorter fiber and higher threshold power for nonlinear effects such as Stimulated Raman Scattering (SRS) and Stimulated Brillouin Scattering (SBS). But the absorption band of Yb-doped fiber is very narrow (<5 nm at the FWHM) and very sharp drop-off occurs around the peak near ˜975 nm. An obvious drawback to pumping this narrow absorption band is that the emitting wavelength of the laser diodes must be tightly controlled to the specified wavelength. A small change in the emitting wavelength of the diodes results in a substantial reduction in the absorption cross-section and enormous amount of unabsorbed pump power will have to be managed making it very impractical in DEW systems. Since the emitting wavelength is directly related to the operating temperature, the coolant temperature must be tightly controlled in order to maintain the proper wavelength as the pump power is increased. This adds complexity to the system increasing cost and SWAP while also requiring setup and stabilization time for the coolant system which is not realistic in operational scenarios. High-power GaAs-based diode lasers produce optical power with extremely high efficiencies, but the spectrum of these Fabry Perot laser diodes is too broad for many applications (>4-5 nm with 95% power content). Narrow spectra (<0.5 nm) can be achieved using monolithically integrated gratings. However, it remains challenging to develop designs that simultaneously achieve high power, high efficiencies and narrow spectra over a wide operating temperature and electrical current (optical power) ranges.

So, they are typically less efficient compared to the DFB and DBR lasers that incorporate 1^{st} order gratings. Furthermore, these higher-order grating stabilized lasers must implement longer gratings to provide sufficient feedback at the Bragg wavelength to discriminate against the Fabry Perot modes in a semiconductor laser cavity to achieve the same operating temperature and current ranges. The following equation describes the coupling constant, κ, which is proportional to the product of the grating index contrast, Δn, the confinement factor in the grating, Γ_{grt} and the Fourier-component for coupling (given by the sine-function of the fractional duty-cycle of the grating period given by the ratio of Λ₁ i.e. fraction of the grating that has lower index to Λ (the period of the grating)) and the grating order, m, and n_{eff} is defined as the modal index or the effective index of the mode.

$$Λ = m \times \frac{λ}{2 {n}_{eff}}$$

$$κ ∝ \frac{2 π}{λ} Δ n {Γ}_{g r t} \frac{Sin ( \frac{m {πΛ}_{1}}{Λ} )}{m π}$$

For the 1^{st} order grating (m=1) and it is maximum at 50% duty cycle; the coupling constant, κ, is:

$$κ ∝ \frac{2}{λ} Δ n {Γ}_{g r t}$$

Whereas, for the 2^{nd} order grating (m=2), the highest coupling constant is achieved when the duty cycle is 25% and the coupling constant, κ, is:

$$κ ∝ \frac{1}{λ} Δ n {Γ}_{g r t}$$

It is clear that even when the duty-cycle is optimized for a maximum coupling constant for a 2^{nd} order grating, the coupling is two times lower when all else is equal. Therefore two times longer gratings are needed to provide the same threshold gain for a DFB laser with a 2^{nd} order grating. The grating length gets progressively longer for higher order gratings.

Some prior designs, such as those described in U.S. Pat. No. 7,586,970, utilize second order partial gratings near the back of the laser diode cavity to minimize the diffraction loss since the total local power (sum of the forward and backward propagating intensity) is smaller in the laser diode compared to the front of the laser diode. Therefore, the net power loss per length of the grating is smaller when a grating is placed near the back. These lasers use partial reflectivity of 2% to 5% at the front facet. However, known designs do not address wavelength locking temperature and electrical current (optical power) ranging as a function of the grating design and/or may be based on a point design.

### Overview

Some embodiments described herein utilize a first order grating and a shorter grating length (as compared to grating-stabilized semiconductor lasers with higher-order gratings) in a semiconductor laser device (e.g., a waveguide) to emit light from one end or both ends of the waveguide. These embodiments may provide sufficient feedback at the Bragg wavelength to suppress Fabry Perot modes.

According to various embodiments in which the semiconductor laser device is arranged to emit light from one end, this grating may be located at the front or rear facet of the semiconductor laser. For example, in a first example, the grating originates only from the rear facet and in a second example, the grating may originate only from the front facet. Further details of these two examples a details are as follows:
In the first example (e.g., “TYPE 1A”), the rear facet may be coated with HR-coating with reflectivity greater than or equal to 95% at the operating center wavelength and +−5 nm or greater spectral range. The operating center wavelength may be approximately 975 nm.
In another first example (e.g., “TYPE 1B”), the HR-coating of the rear facet may be further arranged to provide reflectivity lower than 93% at other wavelengths.
In the second example (e.g., “TYPE 2”), the rear facet may be coated with HR-coating with reflectivity greater than or equal to 95% at the operating center wavelength and +−5 nm or greater spectral range.

A semiconductor laser device arranged to emit light from one or both ends may provide operation of laser diode with fully locked and narrow spectral width (<0.5 nm) from threshold current to 25 Amperes and from 10 C to more than 70 C operating temperature. The operating current range and temperature range can be designed by choosing offset between the semiconductor laser gain peak and the Bragg wavelength. When the grating is located in the back as discussed in TYPE 1A (see above) and TYPE 1B (see above), the optimum grating length for achieving locked and narrow spectrum from threshold current to 25 Amperes and from 10 C to more than 70 C operating temperature may be a grating length in the range of 0.5 mm to 3 mm. When the grating is located in the front as discussed in TYPE 2 device (see above), the optimum grating length for achieving locked and narrow spectrum from threshold current to 25 Amperes and from 10 C to more than 70 C operating temperature may be a grating length in the range 0.05 mm to 0.5 mm.

In examples in which the semiconductor laser device is arranged to emit light from both ends, both the facets may have AR or PR coatings, and the diffraction grating may have two non-contiguous segments that extend to the front and rear facets, respectively.

According to various embodiments in which the semiconductor laser device is arranged to emit light from one end, unlike some known semiconductor laser devices in which the front facet is a partial reflector of typical reflectivity of ˜2% to 5% at the lasing wavelength, the front facet may be coated with antireflection coating. This anti-reflecting coating may have reflectivity in the range of 0.01% to less than 0.5% in the spectral range of ±5 nm or greater (and typically >±10 nm or >±15 nm) from the lasing Bragg wavelength such as the ˜975 nm.

Due to the combination of the grating and the antireflection coating, the effective reflectivity may be greater than 95% at the Bragg wavelength, e.g., ˜975 nm (effective reflectivity may be less elsewhere in the spectral range of the semiconductor gain bandwidth).

### DESCRIPTION WITH REFERENCE TO FIGURES

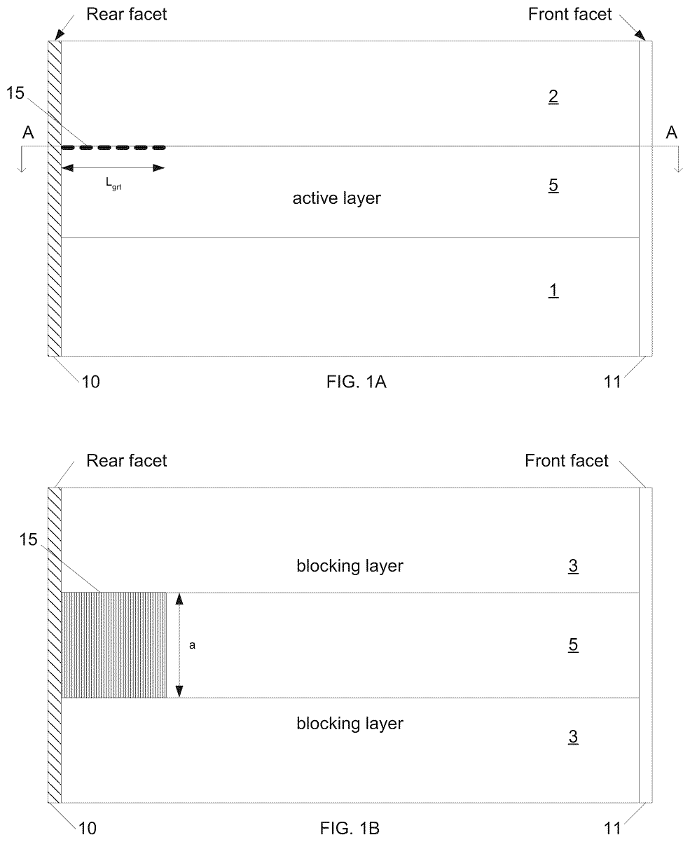

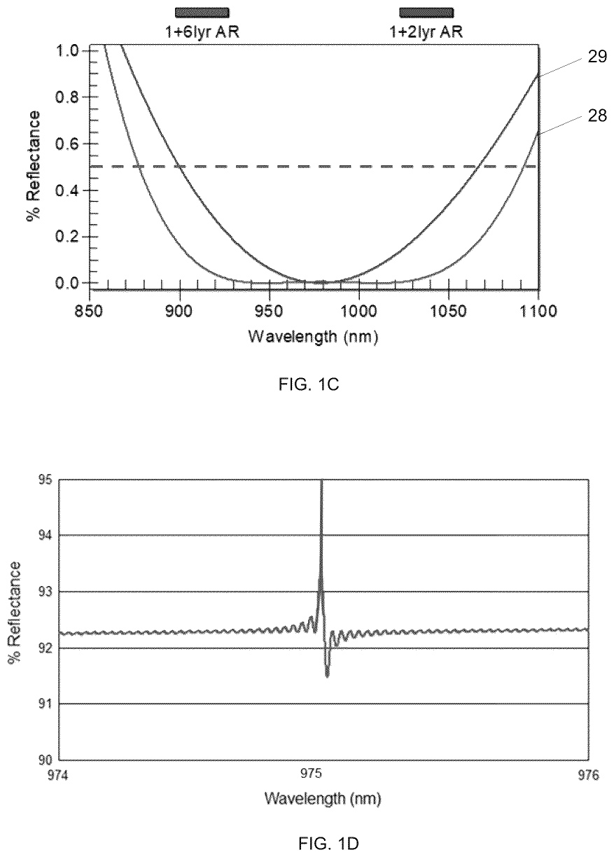

FIG. 1A illustrates a longitudinal cross-sectional view of a semiconductor device (e.g., a laser diode) with an active layer 5 to generate light, and a resonator formed between the rear facet 10 and the front facet 11. The rear facet 10 may be a light reflective facet, e.g., HR-coated. The front facet 11 may be a light emitting facet, e.g., AR-coated or PR-coated. FIG. 1B illustrates a top view of a section of the semiconductor laser device of FIG. 1A, taken from the perspective of arrows A of FIG. 1A.

The buried grating 15 may be positioned within the resonator along only a portion of the length of the active layer 5. The buried grating 15 may extend to, e.g., may terminate at, the rear facet 10, as illustrated. This buried grating 15 may reside at the waveguide and cladding interface (as illustrated) or may reside substantially in the cladding or substantially in the waveguide.

The front facet 11 may have an AR-coating in the range of 0.01% to 0.5% or a PR-coating in the range of 0.5 to 5% in greater than ±5 nm from the laser operating Bragg wavelength of ˜975 nm. The rear facet 10 may have an HR-coating, which may have an effective reflectivity of ≥95% at the Bragg wavelength, e.g., ˜975 nm (effective reflectivity may be less elsewhere in the spectral range of the semiconductor gain bandwidth). In some examples, the HR-coating of the rear facet 10 may be further arranged to provide reflectivity lower than 93% at other wavelengths.

Cladding layer(s) 1 and cladding layer(s) 2 may be any n-cladding layer(s) or any p-cladding layer(s), now known or later developed. In some examples, cladding layer(s) 1 includes an n-cladding and cladding layer(s) 2 includes a p-cladding. Current blocking layer 3 may be any current blocking layer now known or later developed. Arrow “a” shows the width of the buried grating 15.

FIG. 1C is a graph showing reflectivity spectrum of an AR-coating of the front facet 11 illustrated in FIGS. 1A-B, according to one embodiment. In these examples, reflectivity may be less than 0.5% in greater than ±5 nm from the laser operating Bragg wavelength of ˜975 nm. In one example, this AR-coating is a 1+6 layer AR coating shown in the graph as line 28. In another example, this AR-coating is a 1+2 layer AR coating shown in the graph as line 29.

FIG. 1D is a graph showing effective reflectivity spectrum due to a combination of the HR-coating of the rear facet illustrated in FIGS. 1A-B in combination with the buried grating illustrated in FIGS. 1A-B, according to various embodiments. As illustrated, this combination may produce 95% reflectivity at the Bragg wavelength of ˜975 nm in this instance and lower everywhere.

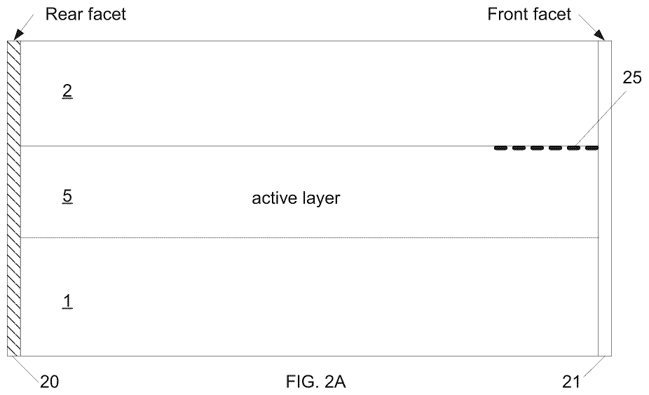

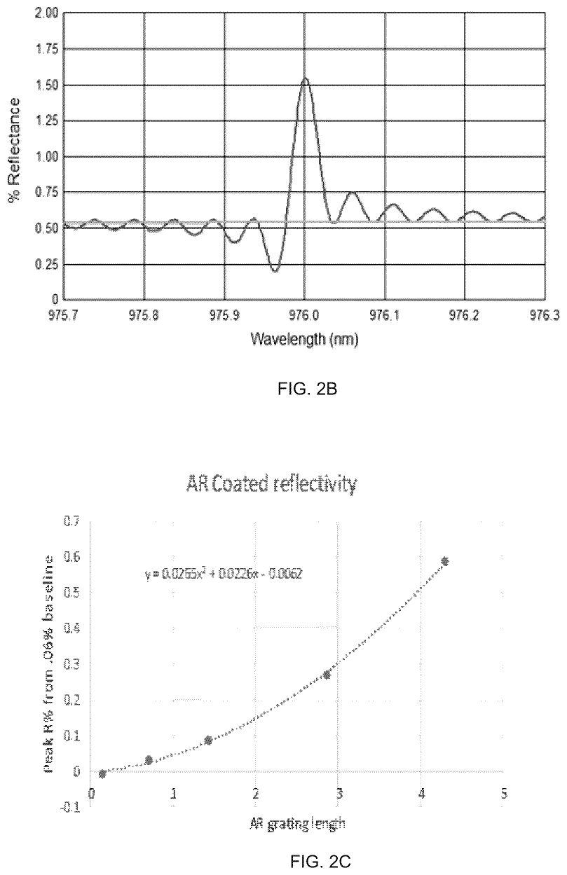

FIG. 2A illustrates a longitudinal cross-sectional view of another semiconductor laser device with a buried grating 25 located at the front facet 21, according to various embodiments. Buried grating 25 may be similar to any other buried grating described herein (such as buried grating 15 of FIG. 1A).

With the buried grating 25 extending to the front facet 21 as shown, the front facet 21 may be coated, not with a partial reflector of typical reflectivity of ˜2% to 5% at the lasing wavelength as with some other front facets, but an antireflection coating with reflectivity in the range of 0.01% to less than 0.3% in the spectral range of ±5 nm or greater (and typically ±10 nm or ±15 nm) from the operating center wavelength such as the ˜975 nm. Furthermore, the effective reflectivity at the Bragg wavelength e.g. ˜975 nm due to the combination of the grating and the AR-coating may be in the range of 0.5% to 5% and less than that value elsewhere in the spectral range of ±5 nm or greater from the lasing Bragg wavelength.

FIG. 2B is a graph showing reflectivity spectrum of the AR-coating of the front facet 21 illustrated in FIG. 2A. As illustrated, effective reflectivity (due to a combination of front facet AR-coating in conjunction with the buried grating 25 located at the front facet 21) may produce reflectivity of 1.5% at the Bragg wavelength and lower everywhere else. This peak reflectivity can go up to 5% in some designs and that can be designed by varying the length (L_{grt} in FIG. 1A) of the buried grating 25. FIG. 2C is a graph showing the dependence of peak reflectivity with grating length at the AR-coated front facet 21. This shows the dependence of peak reflectivity with the grating length at the AR-coated front facet 21 for a semiconductor grating design where Δn=0.0016 and Γ_{grating}=0.0075.

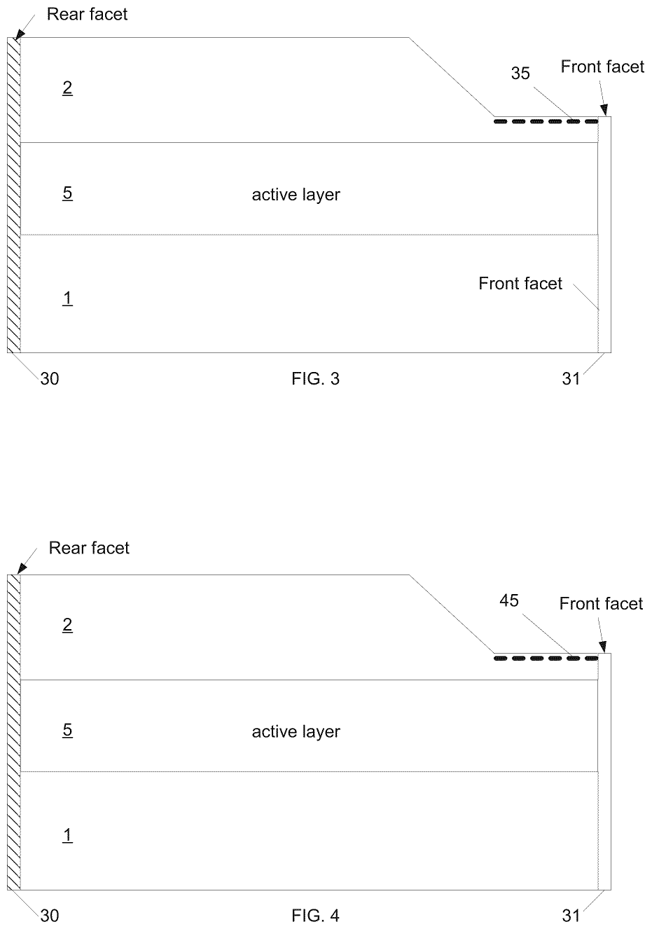

FIG. 3 illustrates a longitudinal cross-sectional view of another semiconductor laser device with a diffraction grating 35 formed from a deposited oxide film over-layer atop a surface semiconductor grating. Front facet 31 may be similar to any front facets described herein, such as front facet 21 (FIG. 2A), e.g., may be AR coated or PR coated.

The surface semiconductor grating 35 may be formed by etching grating features and then depositing a current blocking layer such as a dielectric oxide layer on top of the etched grating features. The coupling strength generated from the difference in index of refraction between the semiconductor and the oxide index layer (based on any formula described herein) may generate the desired feedback.

It should be appreciated that, in other examples, the surface semiconductor grating 35 may be used in the semiconductor laser device shown in FIG. 1A (e.g., extending to the rear facet 10 instead of the front facet 21). In such examples, front facets 21 may have any of the coatings of front facets 11 (FIG. 1A).

FIG. 4 illustrates a longitudinal cross-sectional view of another semiconductor laser device with a diffraction grating 45 formed from a deposited metal over-layer atop a surface semiconductor grating.

The surface semiconductor grating 45 may be formed by etching grating features and then depositing a low loss metal film (e.g., silver or gold or some other low loss metal film) thereon. The metal may be deposited on the semiconductor that is doped properly to form a good Ohmic contact between the semiconductor and the metal so that the grating is “active” i.e. current is not blocked underneath of it. Or, the semiconductor can be terminated with a very low or no doping so that a Schottky contact is formed between the metal and the semiconductor and, therefore, blocks the current entering the underlying grating. The coupling strength generated by the semiconductor to metal index difference may generate the desired feedback.

In some embodiments, silver further optimize the design instead of gold because the real part of the index of refraction of silver is lower than gold, which provides a higher index contrast between the semiconductor and metal (e.g., a higher coupling constant). The penetration of the electric field inside the silver may be smaller due to lower real index. As a result, although the extinction coefficient (imaginary part of the index of refraction) is about the same for these two metals as shown below, the lower field penetration may lead to lower loss for silver.

The surface semiconductor grating 45 also may be AR-coated with reflectivity in the range of 0.01% to 0.5% in greater than ±5 nm from the laser operating Bragg wavelength of ˜975 nm. The effective reflectivity of front facet at the Bragg lasing wavelength, with grating located at the front facet and AR-coating applied to it with reflectivity of 0.01% to 0.5% in greater than ±5 nm from the Bragg lasing wavelength (e.g. ˜975 nm), may be in the range of 0.5% to 5%.

It should be appreciated that, in other examples, the surface semiconductor grating 45 may be used in the semiconductor laser device shown in FIG. 1A (e.g., extending to the rear facet 10 instead of the front facet 21). In such examples, the front facets 21 may have any of the coatings of front facet 11 (FIG. 1A).

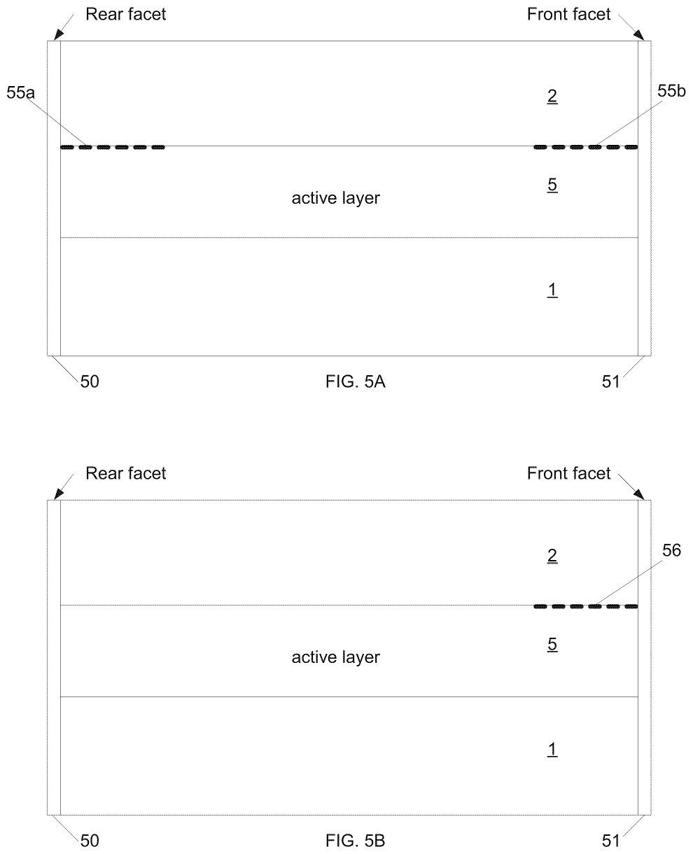

FIG. 5A illustrates a longitudinal cross-sectional view of another semiconductor laser device with buried gratings 55a and 55b located at the rear facet 50 (e.g., a rear output facet) and the front facet 51 (e.g., a front output facet), respectively. Laser diodes can be designed to emit light from both end, and rear and front facets 50 and 51 may both be light permissive (e.g., AR-coated or PR-coated). This may provide an additional advantage to use the buried gratings 55a and 55b as feedback instead of broad band coating on both sides because a combination of the narrow band reflectors on both sides may completely suppress the Fabry Perot modes and this type of laser may have a narrow spectral emission from both ends and may remain so over its operating range in temperature and power.

The buried gratings 55a and 55b may be similar in any respect to buried gratings 15 (FIG. 1A) and 25 (FIG. 2A). For this type of laser, the effective reflectivity of the facet coating and the buried gratings 55a/55b should like the spectrum shown in FIG. 2B, except the peak reflectivity at the Bragg wavelength may be is designed to be in the 0.5% to 15% range and lower elsewhere in the spectrum.

FIG. 5B illustrates a longitudinal cross-sectional view of another semiconducter laser device to emit light from both ends, with a buried diffraction grating 56. The semiconductor laser device of FIG. 5B may be similar in any respect to the semiconductor laser device of FIG. 5A, except that the buried diffraction grating 56 does not extend to one of the light emitting facets 50 and 51 (in the illustrated example, it does not extend to light emitting facet 50).

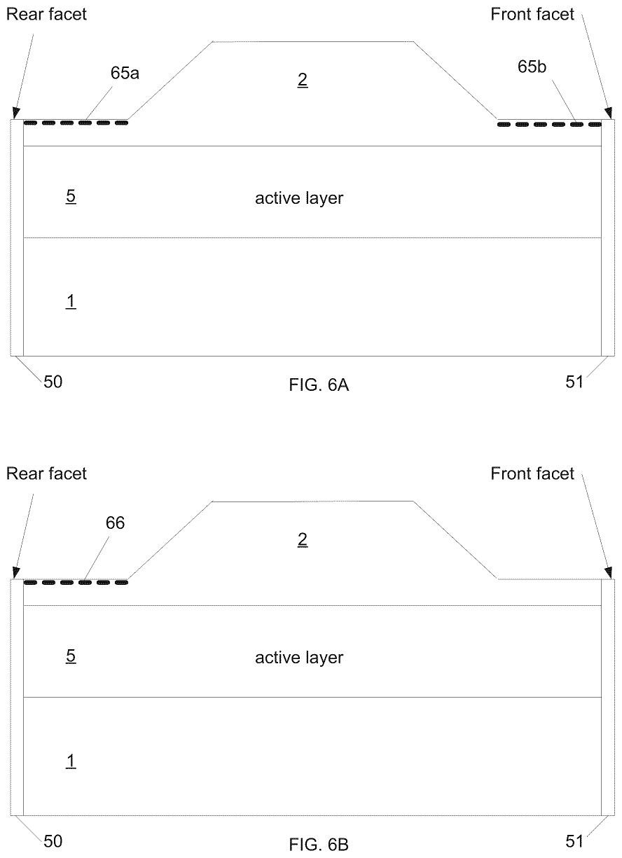

FIG. 6A illustrates a longitudinal cross-sectional view of another semiconductor laser device with diffraction gratings 65a and 65b located at the rear facet 60 and the front facet 61, respectively, in which the diffraction gratings are formed from a deposited oxide film over-layer atop a surface semiconductor grating or a metal over-layer atop a surface semiconductor grating. Each surface semiconductor grating 65a and 65b may be similar in any respect to any surface semiconductor grating described herein (such as diffraction grating 35 of FIG. 3, e.g., a deposited oxide film over-layer atop a surface semiconductor grating or such as diffraction grating 45 of FIG. 4, e.g., a deposited metal over-layer atop a surface semiconductor grating. Rear facet 60 and front facet 61 may be AR-coated or PR-coated similar to any AR-coated or PR-coated rear and front facets described herein, such as rear and front facets 50 and 51 of FIG. 5A.

Surface semiconductor gratings 65a and 65b may have AR coatings with reflectivity in the range of 0.01% to less than 5%. The combination of these surface semiconductor grating coatings and the AR-coated or PR-coated facets may produce an effective reflectivity in the range of 0.5% to 15% at the Bragg lasing wavelength on each side.

FIG. 6B illustrates a longitudinal cross-sectional view of another semiconductor laser device to emit light from both ends, with a diffraction grating 66 that is not buried. The semiconductor laser device of FIG. 6B may be similar in any respect to the semiconductor laser device of FIG. 6A, except that the buried diffraction grating 66 does not extend to one of the light emitting facets 50 and 51 (in the illustrated example, it does not extend to light emitting facet 51).

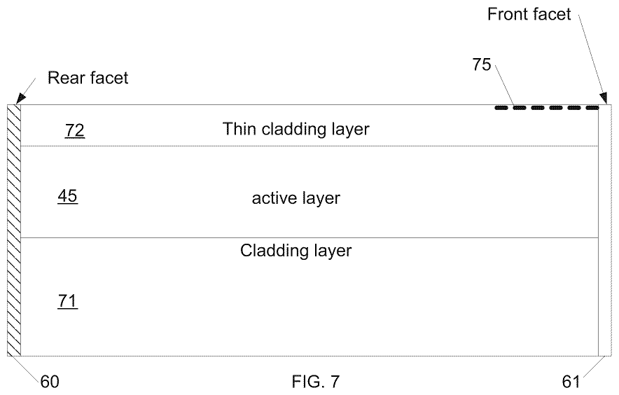

FIG. 7 illustrates a longitudinal cross-sectional view of another semiconductor laser device with a surface semiconductor grating 85 located at the front facet 61, in which one of the cladding layers 71 and 72 is thinner than the other one of the cladding layers 71 and 72. The rear facet 60 and the front facet 61 may be similar to any rear and front facet described herein, such as rear and front facets 10 and 21 of FIG. 3, e.g., HR coated and AR coated, respectively.

This embodiment includes an asymmetric cladding whereby the cladding where the grating resides is thinner compared to the cladding on the other side of the waveguide. This allows formation of the surface semiconductor grating 85 with semiconductor-oxide grating or semiconductor-metal grating and obviates regrowth necessary for the buried grating. The thin cladding layer 72 may be a p-cladding and the other cladding layer 71 may be an n-cladding layer.

In view of the many possible embodiments to which the principles of the disclosed technology may be applied, it should be recognized that the illustrated embodiments are only preferred examples and should not be taken as limiting the scope of the disclosure. We claim as our invention all that comes within the scope and spirit of the appended claims.

1. A semiconductor laser device comprising:
an active layer to generate light;
a front facet positioned at a first end of said active layer, wherein the front facet is a light emitting facet coated with an AR-coating (antireflection) with a reflectivity in the range of 0.01% to less than 0.5% in the spectral range of +−5 nm or greater from an operating center wavelength of semiconductor laser device or coated with a PR-coating (partial reflection) in the range of 0.5 to 5% in the spectral range of +−5 nm or greater from an operating center wavelength of semiconductor laser device;
a rear facet positioned on a second opposite end of said active layer thereby forming a resonator between said front facet and said rear facet; and
a first order diffraction grating positioned within said resonator along only a portion of the length of said active layer, wherein the semiconductor laser device is arranged to emit light from:
both ends, and the diffraction grating has two non-contiguous segments each extending to one of the facets; or
a single end, wherein the rear facet is a rear light reflecting facet with an HR-coating (highly reflective) with reflectivity greater than or equal to 95% at the operating center wavelength and +−5 nm or greater spectral range, and wherein the diffraction grating has a length of in the range of 0.05 mm to 3 mm in length and extends to:
the front facet; or
the rear light reflecting facet, in which case the HR-coating of the rear light reflecting facet is further arranged to provide reflectivity lower than 93% at other wavelengths.

2. The semiconductor laser device of claim 1, wherein the diffraction grating is a buried grating type.

3. The semiconductor laser device of claim 1, wherein the diffraction grating is a surface semiconductor grating type, wherein the diffraction grating is AR-coated with reflectivity in the range of 0.01% to 0.5% in greater than ±5 nm from the laser operating Bragg wavelength of ˜975 nm.

4. The semiconductor laser device of claim 3, wherein the diffraction grating is formed from a deposited oxide film over-layer atop a surface semiconductor grating.

5. The semiconductor laser device of claim 3, wherein the diffraction grating is formed from a deposited metal over-layer atop a surface semiconductor grating.

6. The semiconductor laser device of claim 1, wherein the diffraction grating resides at a waveguide-cladding interface.

7. The semiconductor laser device of claim 4, further comprising a first cladding on a first side of the active layer and a second cladding on a second opposite side of the cladding layer, wherein one of the first and second claddings is thinner than the other of the first and second claddings, and wherein the deposited oxide film over-layer is located on the thinner cladding.

8. The semiconductor laser device of claim 5, wherein the thinner cladding is a p-cladding or the polarity of the claddings are reversed.

9. The semiconductor laser device of claim 1, wherein the rear facet is a light emitting facet coated with an AR or PR coating.

10. The semiconductor laser device of claim 1, wherein a length of a first segment of the non-contiguous segments is 0.05 mm to 3 mm and a length of a second segment of the non-contiguous segments is 0.05 mm to 3 mm.

11. A semiconductor laser device comprising:
an active layer to generate light;
a front facet positioned at a first end of said active layer, wherein the front facet is a light emitting facet coated with an AR-coating (antireflection) with a reflectivity in the range of 0.01% to less than 0.5% in the spectral range of +−5 nm or greater from an operating center wavelength of semiconductor laser device or coated with a PR-coating (partial reflection) in the range of 0.5 to 5% in the spectral range of +−5 nm or greater from an operating center wavelength of semiconductor laser device;
a rear facet positioned on a second opposite end of said active layer thereby forming a resonator between said front facet and said rear facet; and
a first order diffraction grating positioned within said resonator along only a portion of the length of said active layer, wherein the semiconductor laser device is arranged to emit light from both ends, and the diffraction grating has two non-contiguous segments each extending to one of the facets.

12. The semiconductor laser device of claim 11, wherein the diffraction grating is a buried grating type.

13. The semiconductor laser device of claim 11, wherein the diffraction grating is a surface semiconductor grating type, wherein the diffraction grating is AR-coated with reflectivity in the range of 0.01% to 0.5% in greater than ±5 nm from the laser operating Bragg wavelength of ˜975 nm.

14. The semiconductor laser device of claim 13, wherein the diffraction grating is formed from a deposited oxide film over-layer atop a surface semiconductor grating.

15. The semiconductor laser device of claim 13, wherein the diffraction grating is formed from a deposited metal over-layer atop a surface semiconductor grating.

16. The semiconductor laser device of claim 11, wherein the diffraction grating resides at a waveguide-cladding interface.

17. The semiconductor laser device of claim 14, further comprising a first cladding on a first side of the active layer and a second cladding on a second opposite side of the cladding layer, wherein one of the first and second claddings is thinner than the other of the first and second claddings, and wherein the deposited oxide film over-layer is located on the thinner cladding.

18. The semiconductor laser device of claim 15, wherein the thinner cladding is a p-cladding or the polarity of the claddings are reversed.

19. The semiconductor laser device of claim 11, wherein the rear facet is a light emitting facet coated with an AR or PR coating.

20. The semiconductor laser device of claim 11, wherein a length of a first segment of the non-contiguous segments is 0.05 mm to 3 mm and a length of a second segment of the non-contiguous segments is 0.05 mm to 3 mm.

21. A semiconductor laser device comprising:
an active layer to generate light;
a front facet positioned at a first end of said active layer, wherein the front facet is a light emitting facet coated with an AR-coating (antireflection) with a reflectivity in the range of 0.01% to less than 0.5% in the spectral range of +−5 nm or greater from an operating center wavelength of semiconductor laser device or coated with a PR-coating (partial reflection) in the range of 0.5 to 5% in the spectral range of +−5 nm or greater from an operating center wavelength of semiconductor laser device;
a rear facet positioned on a second opposite end of said active layer thereby forming a resonator between said front facet and said rear facet; and
a first order diffraction grating positioned within said resonator along only a portion of the length of said active layer, wherein the semiconductor laser device is arranged to emit light from a single end, wherein the rear facet is a rear light reflecting facet with an HR-coating (highly reflective) with reflectivity greater than or equal to 95% at the operating center wavelength and +−5 nm or greater spectral range, and wherein the diffraction grating has a length of in the range of 0.05 mm to 3 mm in length and extends to:
the front facet; or
the rear light reflecting facet, in which case the HR-coating of the rear light reflecting facet is further arranged to provide reflectivity lower than 93% at other wavelengths.

22. The semiconductor laser device of claim 21, wherein the diffraction grating is a buried grating type.

23. The semiconductor laser device of claim 21, wherein the diffraction grating is a surface semiconductor grating type, wherein the diffraction grating is AR-coated with reflectivity in the range of 0.01% to 0.5% in greater than ±5 nm from the laser operating Bragg wavelength of ˜975 nm.

24. The semiconductor laser device of claim 23, wherein the diffraction grating is formed from a deposited oxide film over-layer atop a surface semiconductor grating.

25. The semiconductor laser device of claim 23, wherein the diffraction grating is formed from a deposited metal over-layer atop a surface semiconductor grating.
